(19) United States
(12) Patent Application Publication
(10) Pub. No.: US 2023/0015307 A1
(43) Pub. Date: Jan. 19, 2023

(54) SEMICONDUCTOR STRUCTURE FABRICATION METHOD, SEMICONDUCTOR STRUCTURE AND MEMORY

(71) Applicant: CHANGXIN MEMORY TECHNOLOGIES, INC., Hefei City (CN)

(72) Inventors: Yuanhao GAO, Hefei City (CN); Shuangshuang Wu, Hefei City (CN)

(21) Appl. No.: 17/455,977

(22) Filed: Nov. 22, 2021

Related U.S. Application Data
(63) Continuation of application No. PCT/CN2021/108235, filed on Jul. 23, 2021.

(30) Foreign Application Priority Data
Jul. 19, 2021 (CN) 202110812620.5

(51) Int. Cl. H01L 21/768; H01L 23/48; H01L 23/528; H01L 21/304; H01L 21/311

(52) U.S. Cl. CPC H01L 21/76898; H01L 23/481; H01L 23/5283; H01L 21/76831; H01L 21/76843; H01L 21/304; H01L 21/31116; H01L 21/31144

(57) ABSTRACT

The present application provides a semiconductor structure fabrication method, a semiconductor structure and a memory. The semiconductor structure fabrication method includes: providing a substrate, the substrate including a first surface and a second surface opposite to each other; forming a first dielectric layer on the first surface of the substrate, wherein semiconductor devices are formed in the first dielectric layer; forming first trenches extending into the substrate in the first dielectric layer; forming a first barrier layer on the first dielectric layer, the first barrier layer covering inner walls of the first trenches and a surface of the first dielectric layer; forming second trenches corresponding to the first trenches on the second surface of the substrate; and forming a second barrier layer on the substrate, the second barrier layer covering the second surface and inner walls of the second trenches.

### CROSS-REFERENCE TO RELATED APPLICATIONS

This application is a continuation application of International Patent Application No. PCT/CN2021/108235, filed on Jul. 23, 2021, which claims priority to Chinese Patent Application No. 202110812620.5, filed with the Chinese Patent Office on Jul. 19, 2021 and entitled “SEMICONDUCTOR STRUCTURE FABRICATION METHOD, SEMICONDUCTOR STRUCTURE AND MEMORY”.

International Patent Application No. PCT/CN2021/108235 and Chinese Patent Application No. 202110812620.5 are incorporated herein by reference in their entireties.

### TECHNICAL FIELD

The present application relates to the field of semiconductor manufacturing technologies, and in particular, to a semiconductor structure fabrication method, a semiconductor structure and a memory.

### BACKGROUND

With the development of semiconductor technologies, due to the constant reduction in feature sizes of integrated circuits and the constant increase in the density of interconnection between devices, conventional two-dimensional packaging can no longer meet the requirements of the industry. Therefore, with the key technological advantages of short-distance interconnection and high-density integration, a stacked packaging method based on Through-Silicon Via (TSV for short) vertical interconnection has become a mainstream direction of the development of packaging technologies.

The TSV technique is a technique which fabricates vertical vias by etching, laser drilling or other methods between different device structures and then deposits a conducting material in the vertical vias by electroplating or other methods to form conducting pillars to achieve electrical interconnection. At present, the TSV process flow mainly depends on a TSV middle process or a TSV last process to form a TSV structure, requiring a large region to be reserved for TSVs, which results in tremendous waste.

Therefore, how to solve the aforementioned problem has become a problem to be solved urgently by those skilled in the art.

### SUMMARY

The embodiments of the present application provides a semiconductor structure fabrication method, including:

providing a substrate, the substrate including a first surface and a second surface opposite to each other;

forming a first dielectric layer on the first surface of the substrate, wherein semiconductor devices are formed in the first dielectric layer;

forming first trenches extending into the substrate in the first dielectric layer;

forming a first barrier layer on the first dielectric layer, the first barrier layer covering inner walls of the first trenches and a surface of the first dielectric layer, wherein the first barrier layer is connected to the semiconductor devices;

forming second trenches corresponding to the first trenches on the second surface of the substrate, wherein the first barrier layer serves as a stop layer when the second trenches are formed; and

forming a second barrier layer on the substrate, the second barrier layer covering the second surface and inner walls of the second trenches, wherein the second barrier layer is connected to the first barrier layer.

The embodiments of the present application provides a semiconductor structure, including:

a substrate including a first surface and a second surface opposite to each other; and

a first dielectric layer formed on the first surface of the substrate, semiconductor devices being formed in the first dielectric layer; wherein the semiconductor structure includes first trenches formed in the first dielectric layer and extending into the substrate; and

a first barrier layer formed on the first dielectric layer, the first barrier layer covering inner walls of the first trenches and a surface of the first dielectric layer, the first barrier layer being connected to the semiconductor devices; wherein the semiconductor structure includes: second trenches formed on the second surface of the substrate and corresponding to the first trenches, the first barrier layer serving as a stop layer when the second trenches are formed; and

a second barrier layer covering the second surface and inner walls of the second trenches, wherein the second barrier layer is connected to the first barrier layer.

The embodiments of the present application provides a memory, including the aforementioned semiconductor structure.

### BRIEF DESCRIPTION OF DRAWINGS

FIG. 1 is a flowchart of a semiconductor structure fabrication method according to an exemplary embodiment; and

FIGS. 2 to 12 are schematic structural diagrams presented by all steps in the flowchart of the semiconductor structure fabrication method according to an exemplary embodiment.

### DETAILED DESCRIPTION

With the development of semiconductor technology, due to the constant reduction in feature sizes of integrated circuits and the constant increase in the density of interconnection between devices, conventional two-dimensional packaging can no longer meet the requirements of the industry. Therefore, with the key technological advantages of short-distance interconnection and high-density integration, a stacked packaging method based on Through-Silicon Via (TSV for short) vertical interconnection has become a mainstream direction of the development of packaging technology.

The TSV technique is a technique which fabricates vertical vias by etching, laser drilling or other methods between different device structures and then deposits a conducting material in the vertical vias by electroplating or other methods to form conducting pillars to achieve electrical interconnection. At present, the TSV process flow mainly depends on a TSV middle process or a TSV last process to form a TSV structure, requiring a large region to be reserved for TSVs, which results in tremendous waste.

In some embodiments, since the cost of silicon on insulator is high, at least ten times that of bulk silicon materials, it is a waste to only fabricate semiconductor devices on the front of silicon on insulator in a conventional way. Moreover, the fabrication of a system on a chip on one plane results in a large structure area. Furthermore, since each subsystem can adopt only one process node, failing to fully utilize a surface of silicon on insulator, the manufacturing cost is high, and the subsystems inside the system cannot be flexibly interconnected. Therefore, how to design a system on a chip with powerful functionality in which semiconductor devices can be fabricated on both the front and back of silicon on insulator has become a problem confronting those skilled in the art.

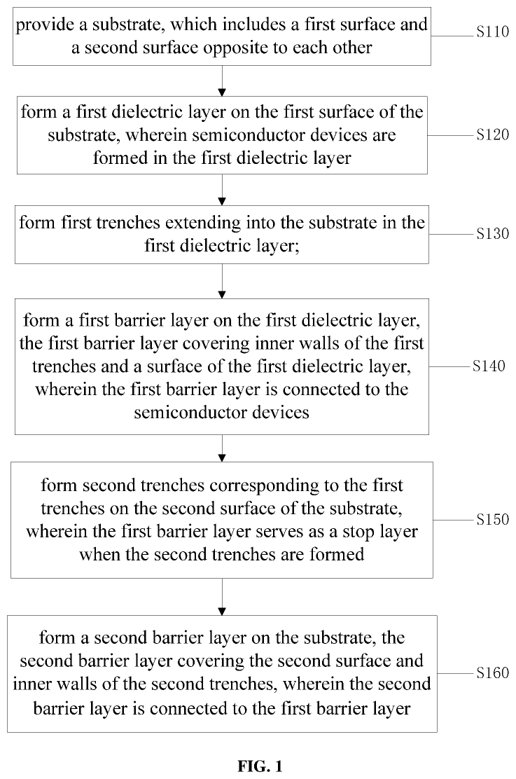

As shown in FIG. 1, the present application provides a semiconductor structure fabrication method, including:

(S110) providing a substrate, the substrate including a first surface and a second surface opposite to each other;

(S120) forming a first dielectric layer on the first surface of the substrate, wherein semiconductor devices are formed in the first dielectric layer;

(S130) forming first trenches extending into the substrate in the first dielectric layer;

(S140) forming a first barrier layer on the first dielectric layer, the first barrier layer covering inner walls of the first trenches and a surface of the first dielectric layer, wherein the first barrier layer is connected to the semiconductor devices;

(S150) forming second trenches corresponding to the first trenches on the second surface of the substrate, wherein the first barrier layer serves as a stop layer when the second trenches are formed;

(S160) forming a second barrier layer on the substrate, the second barrier layer covering the second surface and inner walls of the second trenches, wherein the second barrier layer is connected to the first barrier layer.

In the embodiments of the present application, in a first aspect, the TSV process flow is optimized; by employing a TSV first process to form the first trenches and the second trenches on the two opposite surfaces of the substrate (i.e., wafer) respectively, the problems of large wafer fabrication area and excessive cost caused by the fabrication of semiconductor devices and the reservation of a TSV fabrication area on a same surface of a wafer can be solved; according to the present application, by forming the second trenches on the second surface of the substrate, the number of the first trenches of the first surface of the substrate can be reduced, effectively controlling the wafer fabrication area and saving the fabrication cost of a semiconductor. In a second aspect, since the two opposite surfaces of the substrate are sufficiently utilized to form a TSV structure in the form of a 3D architecture composed of the first trenches and the second trenches and the second barrier layer in the second trenches is in metallic interconnection with the first barrier layer in the first trenches, a 3D architecture of subsystems in a system on a chip is achieved, the interconnection between the subsystems is more flexible, interconnection lines are shorter, and the performance of the semiconductor is improved.

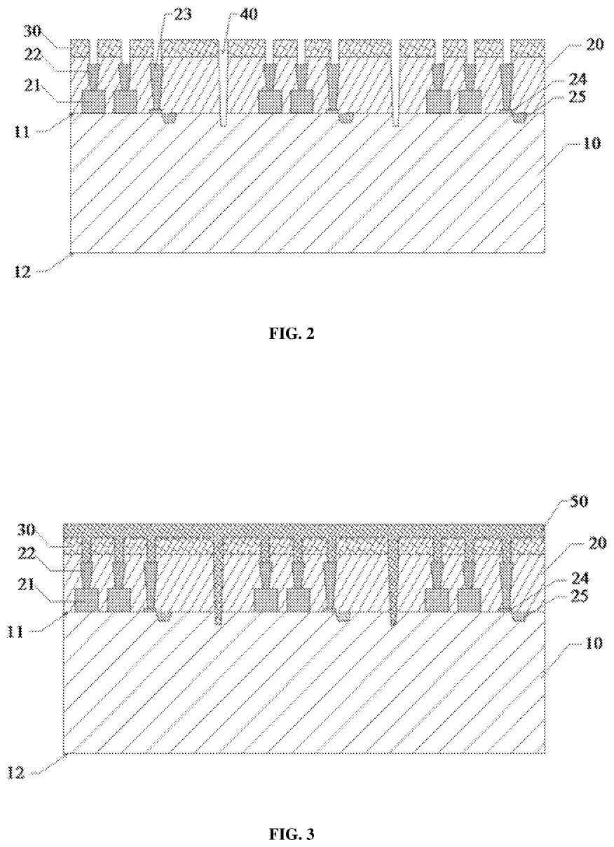

In some embodiments, FIGS. 2 to 7 provide schematic structural diagrams presented by steps S110 to S140 in the flow of the semiconductor structure fabrication method according to the embodiment of the present application. FIGS. 2 to 7 are sectional views of a semiconductor structure in the manufacturing process, which illustrate a substrate 10, a first dielectric layer 20 formed on the substrate 10, a first surface 11 and a second surface 12 of the substrate 10, and formed first trenches 40.

Any substrate 10 in the prior art may be used as the substrate 10 as required, and a structure and material of the substrate 10 may also be adaptively adjusted as required. For example, the material of the substrate 10 may be one or a combination of any of silicon, germanium, silicon germanium, silicon carbide, gallium arsenide, indium gallium, silicon on insulator (SOI) or germanium on insulator (GOI).

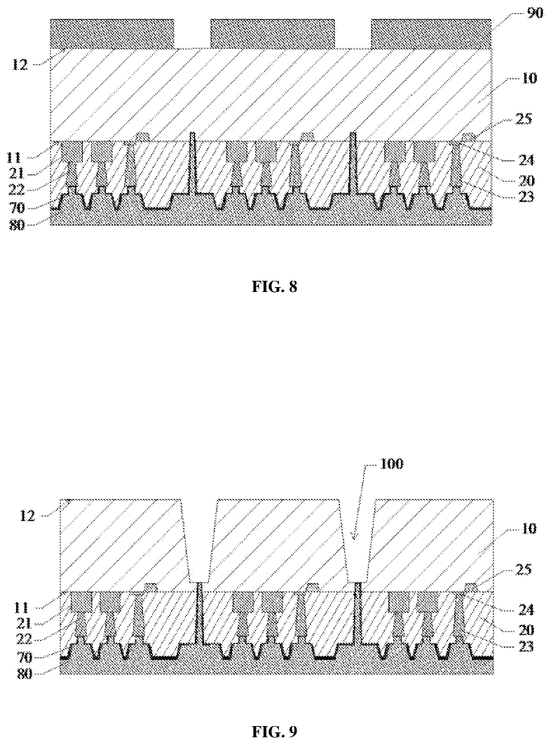

In some embodiments, referring to FIG. 7, in step S120, the first dielectric layer 20 is formed on the first surface 11 of the substrate 10, wherein semiconductor devices are formed in the first dielectric layer. As shown in FIGS. 2 to 12, the semiconductor device includes a capacitor structure 21, a first metal plug 22, a second metal plug 23, a device 24 and a trench isolator 25. The capacitor structure 21 is formed on the first surface 11 of the substrate 10, the first metal plug 22 is connected to the capacitor structure 21, and a top exposed surface of the first metal plug 22 covers a first barrier layer 70. The trench isolator 25 is formed in the substrate 10, the device 24 is formed on the first surface 11 of the substrate 10, the second metal plug 23 is connected to the device 24, and the top exposed surface of the second metal plug 23 covers the first barrier layer 70. A material of the first dielectric layer 20 may be selected from at least one of SiN (silicon nitride), SiO₂ (silicon oxide), SiON (silicon oxynitride) and BARC (bottom anti-reflective coating). As shown in FIG. 7, the semiconductor devices are formed on the first surface 11 of the substrate 10. The present application employs a deposition process to form the first dielectric layer 20 on the first surface 11 of the substrate 10, with the first dielectric layer 20 formed to cover the semiconductor devices. The semiconductor devices include, but are not limited to, NMOS devices, PMOS devices, CMOS devices, resistors, capacitors, inductors or the like.

In some embodiments, referring to FIGS. 2 to 12, in step S130, the first trenches 40 extending into the substrate 10 is formed in the first dielectric layer 20, wherein the first trenches 40 are formed in the substrate 10 by employing the TSV first process. It can be seen from the above accompanying drawings that the first trenches 40 running through the first dielectric layer 20 and extending into the substrate 10 are formed by processing a surface of the first dielectric layer 20 away from the substrate 10 by employing the TSV first process. The first trenches 40 are formed between the adjacent semiconductor devices.

In some embodiments, referring to FIG. 7, in step S140, the first barrier layer 70 is formed on the first dielectric layer 20, the first barrier layer 70 covering inner walls of the first trenches 40 and a surface of the first dielectric layer 20, wherein the first barrier layer 70 is connected to the semiconductor devices. It should be understood that in some embodiments, the first barrier layer 70 is a metallic interconnection layer. Continuing to refer to FIG. 7, a plurality of trenches are formed in the first dielectric layer 20, including the first trenches 40, with each trench correspondingly formed on the top of each semiconductor device to expose the surface of the semiconductor device, and the first barrier layer 70 is formed to cover the surface of the first dielectric layer 20, and is connected to the exposed surface of each semiconductor device.

In some embodiments, the forming the first trenches 40 extending into the substrate 10 in the first dielectric layer 20 in step S130 includes:

(S131) forming a first mask pattern on the first dielectric layer 20;

Referring to FIG. 2, the first mask pattern is formed on a surface of the first dielectric layer 20 away from the substrate 10.

(S132) etching the first dielectric layer 20 by utilizing the first mask pattern to form the first trenches 40 extending from the first dielectric layer 20 into the substrate 10.

Continuing to refer to FIG. 2, the first mask pattern defines etching windows, and the first dielectric layer 20 and the substrate 10 are etched according to the etching windows to form the trenches in the first dielectric layer 20. The trenches include the trenches corresponding to the semiconductor devices and the first trenches 40. The trenches corresponding to the semiconductor devices use the semiconductor devices as an etching stop layer and expose the surfaces of the semiconductor devices after etching. The first trenches 40 are formed to run through the first dielectric layer 20 and stop in the substrate 10.

In some embodiments, the forming a first mask pattern on the first dielectric layer 20 in step S131 includes:

(S1311) forming a first hard mask layer 30 on the first dielectric layer 20.

The first hard mask layer 30 is formed on a surface of the first dielectric layer 20 away from the substrate 10 by employing the deposition process.

(S1312) forming the first mask pattern on the first hard mask layer 30.

In some embodiments, a photoresist layer is formed on the first hard mask layer 30 by employing a spin-coating process, the photoresist layer is patterned by employing an exposure process, and the first hard mask layer 30 is etched according to the patterned photoresist layer to form a first mask pattern.

In some embodiments, subsequent to the etching the first dielectric layer 20 by utilizing the first mask pattern to form the first trenches 40 extending from the first dielectric layer 20 into the substrate 10 in step S132, the semiconductor structure fabrication method further includes:

(S170) forming a second hard mask layer 50 covering the first mask pattern and the first trenches 40;

Referring to FIG. 3, the second hard mask layer 50 is formed on a surface of the first mask pattern (formed by patterning the first hard mask layer 30 using the etching process) away from the substrate 10, and fills the etching windows of the first mask pattern and the trenches formed in the first dielectric layer 20.

(S180) forming a patterned photoresist layer 60 on the second hard mask layer 50.

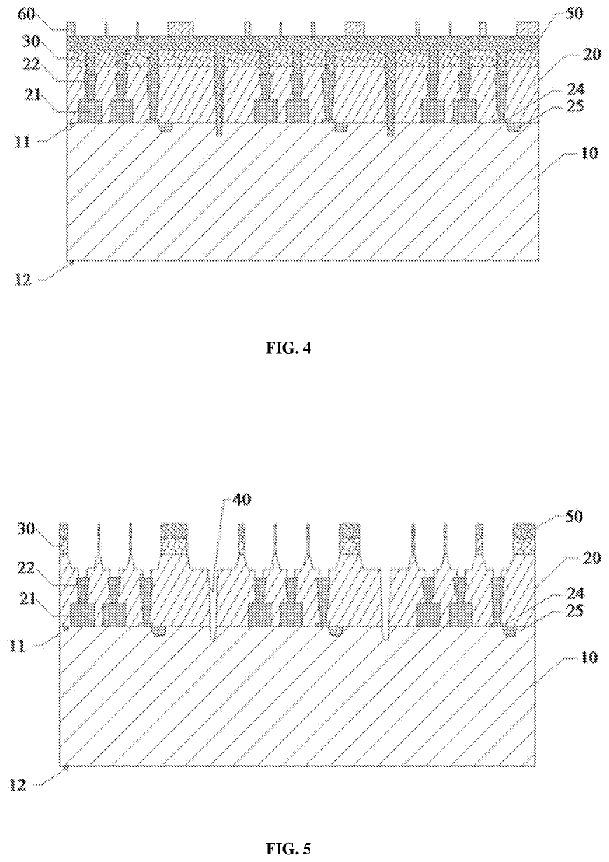

Referring to FIG. 4, the patterned photoresist layer 60 is formed on a surface of the second hard mask layer 50 away from the substrate 10. It can be understood that the patterned photoresist layer 60 can be formed on the second hard mask layer 50 by employing the spin-coating process and patterned by employing the exposure process.

(S190) transferring the pattern of the patterned photoresist layer 60 to the first dielectric layer 20 by employing a dry etching process.

Referring to FIG. 5, the second hard mask layer 50 is dry-etched according to the patterned photoresist layer 60, and the pattern of the patterned photoresist layer 60 is transferred to the second hard mask layer 50, the first hard mask layer 30 and the first dielectric layer 20, so that one side of the first dielectric layer 20 away from the substrate 10 is formed into a patterned structure.

In some other embodiments, subsequent to the transferring the pattern of the patterned photoresist layer 60 to the first dielectric layer 20 by employing a dry etching process in step S190, the semiconductor structure fabrication method further includes:

(S191) removing the hard masks and the photoresist on the first dielectric layer 20 by employing a wet cleaning process.

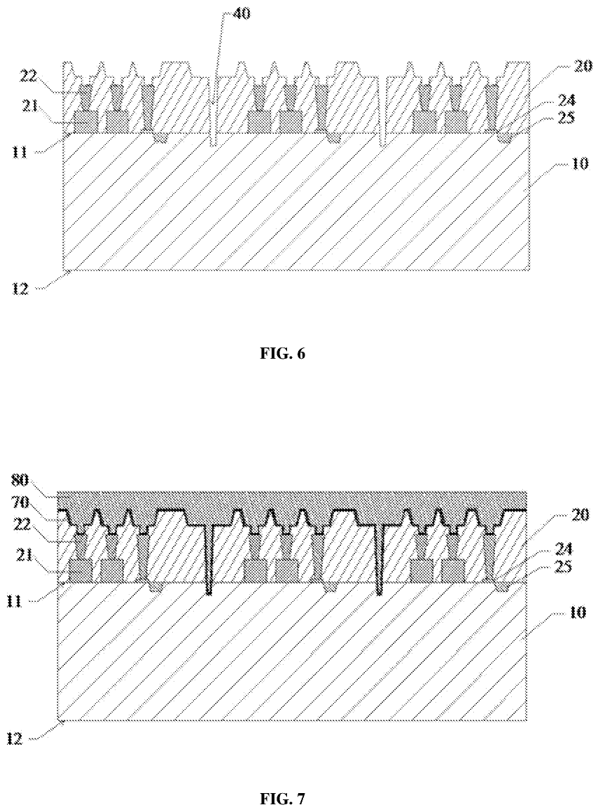

The hard masks and the photoresist on the first dielectric layer 20 are removed by employing the wet cleaning process, and the hard masks include the first hard mask layer 30 and the second hard mask layer 50 which are laminated on the first dielectric layer 20 after pattern transferring. Referring to FIG. 6, FIG. 6 shows a semiconductor structure after cleaning. It can be seen in the drawing that a pattern structure has been formed on one side of the first dielectric layer 20 away from the substrate 10, a trench is correspondingly formed over each semiconductor device to expose a surface of the semiconductor device, and the formed first trenches 40 expose a surface of the substrate 10.

In yet other embodiments, subsequent to the forming a first barrier layer 70 on the first dielectric layer 20 in step S140, the semiconductor structure fabrication method further includes:

(S200) forming a first metal layer 80 covering the first barrier layer 70.

Referring to FIG. 7, a first metal layer 80 is formed on one side of the first dielectric layer 20 where the pattern structure is formed, and covers the surface of the first barrier layer 70, and the first barrier layer 70 is located between the first metal layer 80 and the first dielectric layer 20. The first metal layer 80 fills the trenches in the first dielectric layer 20, specifically including the trenches corresponding to the semiconductor devices and the first trenches 40. A material of the first metal layer 80 may be copper.

In some embodiments, subsequent to the forming second trenches 100 corresponding to the first trenches 40 on the second surface 12 of the substrate 10 in step S150, the semiconductor structure fabrication method further includes:

(S210) turning over the substrate 10.

The substrate 10 is turned over, so that the second surface 12 of the substrate 10 serves as a fabrication surface in the semiconductor structure manufacturing process. Referring to FIGS. 8 to 12, it can be seen that the substrate 10 is turned over by 180 degrees.

(S220) thinning the second surface 12 of the substrate 10.

The second surface 12 is lapped by employing a chemical mechanical polish (CMP) process to reduce the thickness of the substrate 10.

In some embodiments, the forming second trenches 100 corresponding to the first trenches 40 on the second surface 12 of the substrate 10 in step S150 includes:

(S151) forming a second mask pattern on the second surface 12 of the substrate 10.

Referring to FIG. 8, a second mask pattern is formed on the second surface 12 of the substrate 10, and the second mask pattern defines etching windows.

(S152) etching the substrate 10 by utilizing the second mask pattern to form the second trenches 100 stopping at the first barrier layer 70.

Referring to FIG. 9, the substrate 10 is etched according to the etching windows defined by the second mask pattern and with the first barrier layer 70 as a stop layer to form second trenches 100 stopping at the first barrier layer 70.

In some embodiments, the forming a second mask pattern on the second surface 12 of the substrate 10 in step S151 includes:

(S1511) forming a third hard mask layer 90 on the second surface 12 of the substrate 10.

Referring to FIG. 8, the third hard mask layer 90 is formed on the second surface 12 of the substrate 10 by employing the deposition process.

(S1512) processing the third hard mask layer 90 by employing the exposure process to form the second mask pattern.

A photoresist layer is formed on the third hard mask layer 90 by employing the spin-coating process, the photoresist layer is patterned by employing the exposure process, and the third hard mask layer 90 is etched according to the patterned photoresist layer to form a second mask pattern, which defines etching windows for the etching of the second trenches 100.

In some embodiments, prior to the forming a second barrier layer 120 on the substrate 10 in step S160, the semiconductor structure fabrication method further includes:

(S230) forming a second dielectric layer 110 on the substrate 10, the second dielectric layer 110 covering the second surface 12 and inner walls of the second trenches 100.

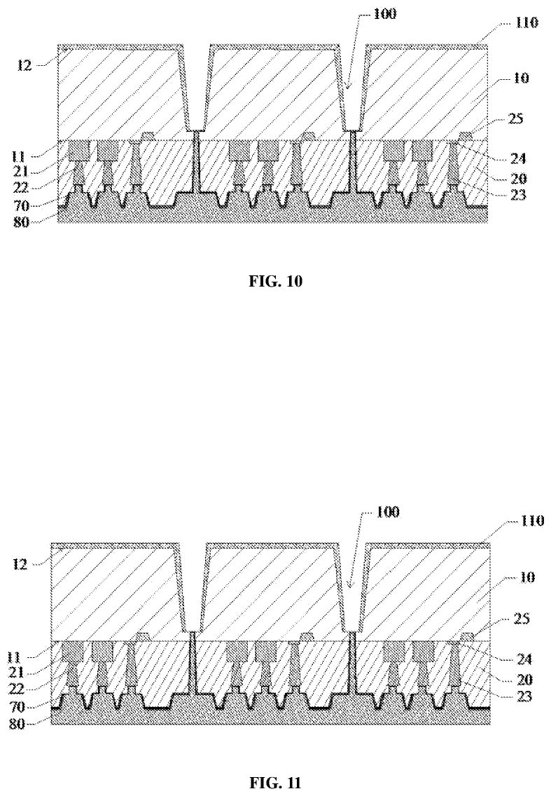

Referring to FIG. 10, a second dielectric layer 110 is formed on the substrate 10 by employing the deposition process, with the second dielectric layer 110 formed to cover the second surface 12 and inner walls of the second trenches 100. A material of the second dielectric layer 110 may be selected from at least one of SiN (silicon nitride), SiO₂ (silicon oxide), SiON (silicon oxynitride) and BARC (bottom anti-reflective coating). Continuing to refer to FIG. 10, the second dielectric layer 110 located at bottoms of the second trenches 100 is connected to the first barrier layer 70.

In some embodiments, subsequent to the forming a second dielectric layer 110 on the substrate 10 in step S230, the semiconductor structure fabrication method further includes:

(S240) removing the second dielectric layer 110 formed at the bottoms of the second trenches 100 by employing the etching process.

Referring to FIG. 11, the second dielectric layer 110 at the bottoms of the second trenches 100 is etched with the first barrier layer 70 as an etching stop layer to expose the surface of the first barrier layer 70.

In some embodiments, subsequent to the forming a second barrier layer 120 on the substrate 10 in step S160, the semiconductor structure fabrication method further includes:

(S250) forming a second metal layer 130 covering the second barrier layer 120.

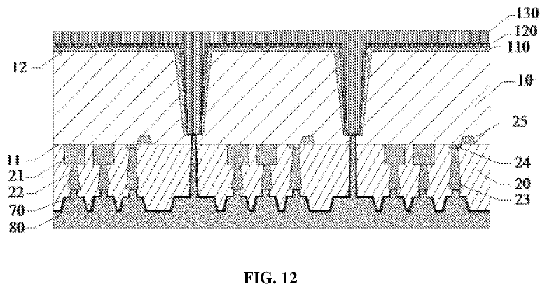

Referring to FIG. 12, a second metal layer 130 is formed on a surface of the second barrier layer 120, with the second barrier layer 120 located between the second metal layer 130 and the second dielectric layer 110. The second metal layer 130 fills the second trenches 100. Continuing to refer to FIG. 12, the second barrier layer 120 and the first barrier layer 70 are connected at the bottoms of the second trenches 100, achieving the interconnection between the first barrier layer 70 and the second barrier layer 120. A material of the second metal layer 130 is copper.

In the embodiments of the present application, in a first aspect, the TSV process flow is optimized; by employing a TSV first process to form the first trenches 40 and the second trenches 100 on the two opposite surfaces of the substrate 10 (i.e., wafer) respectively, the problems of large wafer fabrication area and excessive cost caused by the fabrication of semiconductor devices and the reservation of a TSV fabrication area on a same surface of the wafer can be solved; according to the present application, by forming the second trenches 100 on the second surface 12 of the substrate 10, the number of the first trenches 40 of the first surface 11 of the substrate 10 can be reduced, effectively controlling the wafer fabrication area and saving the fabrication cost of a semiconductor. In a second aspect, since the two opposite surfaces of the substrate 10 are sufficiently utilized to form a TSV structure in the form of a 3D architecture composed of the first trenches 40 and the second trenches 100 and the second barrier layer 120 in the second trenches 100 is in metallic interconnection with the first barrier layer 70 in the first trenches 40, a 3D architecture of subsystems in a system on a chip is achieved, the interconnection between the subsystems is more flexible, interconnection lines are shorter, and the performance of the semiconductor is improved.

In some embodiments, numbers of the first trenches 40 and the second trenches 100 are plural, and the plurality of second trenches 100 and the plurality of first trenches 40 are arranged in one-to-one correspondence. The first trench 40 is formed between two adjacent semiconductor devices.

In the embodiments of the present application, since the two opposite surfaces of the substrate 10 are sufficiently utilized to form a TSV structure in the form of a 3D architecture composed of the first trenches 40 and the second trenches 100 and the second barrier layer 120 in the second trenches 100 is in metallic interconnection with the first barrier layer 70 in the first trenches 40, a 3D architecture of subsystems in a system on a chip is achieved, the interconnection between the subsystems is more flexible, interconnection lines are shorter, and the performance of the semiconductor is improved.

In some embodiments, a cross section of the second trench 100 is wedge-shaped, and an opening size of the second trench 100 is gradually reduced along a direction from the second surface 12 to the first surface 11.

According to a second aspect of the present application, the present application provides a semiconductor structure, which includes a substrate 10, a first dielectric layer 20, a first barrier layer 70 and a second barrier layer 120. The substrate 10 includes a first surface 11 and a second surface 12 opposite to each other. A first dielectric layer 20 is formed on the first surface 11 of the substrate 10, and semiconductor devices are formed in the first dielectric layer 20; and the semiconductor structure includes first trenches 40 formed in the first dielectric layer 20 and extending into the substrate 10. The first barrier layer 70 is formed on the first dielectric layer 20 and covers inner walls of the first trenches 40 and a surface of the first dielectric layer 20, and the first barrier layer 70 is connected to the semiconductor devices. The semiconductor structure includes second trenches 100 formed on the second surface 12 of the substrate 10 and corresponding to the first trenches 40, and the first barrier layer 70 serves as a stop layer when the second trenches 100 are formed. The second barrier layer 120 is formed on the substrate 10 and covers the second surface 12 and inner walls of the second trenches 100. The second barrier layer 120 is connected to the first barrier layer 70.

In the embodiments of the present application, in a first aspect, the TSV process flow is optimized; by employing a TSV first process to form the first trenches 40 and the second trenches 100 on the two opposite surfaces of the substrate 10 (i.e., wafer) respectively, the problems of large wafer fabrication area and excessive cost caused by the fabrication of semiconductor devices and the reservation of a TSV fabrication area on a same surface of the wafer can be solved; according to the present application, by forming the second trenches 100 on the second surface 12 of the substrate 10, the number of the first trenches 40 of the first surface 11 of the substrate 10 can be reduced, effectively controlling the wafer fabrication area and saving the fabrication cost of a semiconductor. In a second aspect, since the two opposite surfaces of the substrate 10 are sufficiently utilized to form a TSV structure in the form of a 3D architecture composed of the first trenches 40 and the second trenches 100 and the second barrier layer 120 in the second trenches 100 is in metallic interconnection with the first barrier layer 70 in the first trenches 40, a 3D architecture of subsystems in a system on a chip is achieved, the interconnection between the subsystems is more flexible, interconnection lines are shorter, and the performance of the semiconductor is improved.

In some embodiments, the semiconductor structure further includes a first metal layer 80, which is formed to cover the first barrier layer 70.

In some embodiments, the semiconductor structure further includes a second dielectric layer 110, which is formed on the substrate 10. The second dielectric layer 110 covers the second surface 12 and the inner walls of the second trenches 100.

In some embodiments, the semiconductor structure further includes a second metal layer 130, which is formed to cover the second barrier layer 120.

In some embodiments, the numbers of the first trenches 40 and the second trenches 100 are plural, and the plurality of second trenches 100 and the plurality of first trenches 40 are arranged in one-to-one correspondence.

In the embodiments of the present application, since the two opposite surfaces of the substrate 10 are sufficiently utilized to form a TSV structure in the form of a 3D architecture composed of the first trenches 40 and the second trenches 100 and the second barrier layer 120 in the second trenches 100 is in metallic interconnection with the first barrier layer 70 in the first trenches 40, a 3D architecture of subsystems in a system on a chip is achieved, the interconnection between the subsystems is more flexible, interconnection lines are shorter, and the performance of the semiconductor is improved.

It can be understood that the semiconductor structure fabricated according to the embodiments described above can be applied to the fabrication of various integrated circuit (IC). An IC according to the present application is, for example, a memory circuit, such as a random access memory (RAM), a dynamic RAM (DRAM), a synchronous DRAM (SDRAM), a static RAM (SRAM), or a read-only memory (ROM) or the like. The IC according to the present application may also be a logic device, such as a programmable logic array (PLA), an application specific integrated circuit (ASIC), a merged DRAM logic integrated circuit (buried DRAM), a radio frequency circuit or any other circuit device. The IC chip according to the present application may be used in, for example, electronic products for consumers, such as personal computers, portable computers, game consoles, cellular phones, personal digital assistants, video cameras, digital cameras, mobile phones and other electronic products.

According to a third aspect of the present application, the present application provides a memory, including the aforementioned semiconductor structure.

In the description of the present specification, the description of reference terms, such as “some embodiments”, “other embodiments” and “ideal embodiments”, means that the specific features, structures, materials or characteristics described in the embodiments or examples are included in at least one embodiment or example of the present application. In the present specification, the schematic description of the aforementioned terms does not necessarily refer to the same embodiment or example.

All the technical features of the aforementioned embodiments can be combined arbitrarily. In order to make the description concise, not all possible combinations of the technical features in the aforementioned embodiments are described. However, as long as there is no contradiction between the combinations of these technical features, they should be considered as the scope recorded in the present specification.

The aforementioned embodiments only represent several embodiments of the present application, and although their descriptions are specific and detailed, they cannot be understood as a limitation to the scope of the present patent application. It should be pointed out that those of ordinary skill in the art can also make a plurality of alterations and improvements without departing from the concept of the present application, and these alterations and improvements shall fall within the protection scope of the present application. Therefore, the protection scope of the present patent application shall be subject to the appended claims.

What is claimed is:

1. A semiconductor structure fabrication method, comprising:
providing a substrate, the substrate comprising a first surface and a second surface opposite to each other;
forming a first dielectric layer on the first surface of the substrate, wherein semiconductor devices are formed in the first dielectric layer;
forming first trenches extending into the substrate in the first dielectric layer;
forming a first barrier layer on the first dielectric layer, the first barrier layer covering inner walls of the first trenches and a surface of the first dielectric layer, wherein the first barrier layer is connected to the semiconductor devices;
forming second trenches corresponding to the first trenches on the second surface of the substrate, wherein the first barrier layer serves as a stop layer when the second trenches are formed; and
forming a second barrier layer on the substrate, the second barrier layer covering the second surface and inner walls of the second trenches, wherein the second barrier layer is connected to the first barrier layer.

2. The semiconductor structure fabrication method according to claim 1, wherein the forming first trenches extending into the substrate in the first dielectric layer comprises:
forming a first mask pattern on the first dielectric layer; and
etching the first dielectric layer by utilizing the first mask pattern to form the first trenches extending from the first dielectric layer into the substrate.

3. The semiconductor structure fabrication method according to claim 2, wherein the forming a first mask pattern on the first dielectric layer comprises:
forming a first hard mask layer on the first dielectric layer; and
forming a first mask pattern on the first hard mask layer.

4. The semiconductor structure fabrication method according to claim 2, subsequent to the etching the first dielectric layer by utilizing the first mask pattern to form the first trenches extending from the first dielectric layer into the substrate, further comprising:
forming a second hard mask layer covering the first mask pattern and the first trenches;
forming a patterned photoresist layer on the second hard mask layer; and
transferring a pattern of the patterned photoresist layer to the first dielectric layer by employing a dry etching process.

5. The semiconductor structure fabrication method according to claim 4, subsequent to the transferring the pattern of the patterned photoresist layer to the first dielectric layer by employing a dry etching process, further comprising:
removing the first hard mask layer, the second hard mask layer, and the patterned photoresist layer on the first dielectric layer by employing a wet cleaning process.

6. The semiconductor structure fabrication method according to claim 1, subsequent to the forming a first barrier layer on the first dielectric layer, further comprising:
forming a first metal layer covering the first barrier layer.

7. The semiconductor structure fabrication method according to claim 1, prior to the forming second trenches corresponding to the first trenches on the second surface of the substrate, further comprising:
thinning the second surface of the substrate.

8. The semiconductor structure fabrication method according to claim 1, wherein the forming second trenches corresponding to the first trenches on the second surface of the substrate comprises:
forming a second mask pattern on the second surface of the substrate; and
etching the substrate by utilizing the second mask pattern to form the second trenches stopping at the first barrier layer.

9. The semiconductor structure fabrication method according to claim 8, wherein the forming a second mask pattern on the second surface of the substrate comprises:
forming a third hard mask layer on the second surface of the substrate; and
processing the third hard mask layer by employing an exposure process to form the second mask pattern.

10. The semiconductor structure fabrication method according to claim 1, prior to the forming a second barrier layer on the substrate, further comprising:
forming a second dielectric layer on the substrate, the second dielectric layer covering the second surface and inner walls of the second trenches.

11. The semiconductor structure fabrication method according to claim 10, subsequent to the forming a second dielectric layer on the substrate, further comprising:
removing the second dielectric layer formed at bottoms of the second trenches by employing an etching process.

12. The semiconductor structure fabrication method according to claim 1, subsequent to the forming a second barrier layer on the substrate, further comprising:
forming a second metal layer covering the second barrier layer.

13. The semiconductor structure fabrication method according to claim 1, wherein numbers of the first trenches and the second trenches are plural, and the plurality of second trenches and the plurality of first trenches are arranged in one-to-one correspondence.

14. The semiconductor structure fabrication method according to claim 1, wherein
a cross section of the second trench is wedge-shaped, and an opening size of the second trench is gradually reduced along a direction from the second surface to the first surface.

15. A semiconductor structure, comprising:
a substrate comprising a first surface and a second surface opposite to each other; and
a first dielectric layer formed on the first surface of the substrate, semiconductor devices being formed in the first dielectric layer; wherein the semiconductor structure comprises first trenches formed in the first dielectric layer and extending into the substrate; and
a first barrier layer formed on the first dielectric layer, the first barrier layer covering inner walls of the first trenches and a surface of the first dielectric layer, the first barrier layer being connected to the semiconductor devices; wherein the semiconductor structure comprises: second trenches formed on the second surface of the substrate and corresponding to the first trenches, the first barrier layer serving as a stop layer when the second trenches are formed; and
a second barrier layer covering the second surface and inner walls of the second trenches, wherein the second barrier layer is connected to the first barrier layer.

16. The semiconductor structure according to claim 15, further comprising:
a first metal layer formed to cover the first barrier layer.

17. The semiconductor structure according to claim 15, further comprising:
a second dielectric layer covering the second surface and inner walls of the second trenches.

18. The semiconductor structure according to claim 15, further comprising:
a second metal layer formed to cover the second barrier layer.

19. The semiconductor structure according to claim 15, wherein
numbers of the first trenches and the second trenches are plural, and the plurality of second trenches and the plurality of first trenches are arranged in one-to-one correspondence.

20. A memory, comprising the semiconductor structure according to claim 15.
